(19) United States
(12) Patent Application Publication
(10) Pub. No.: US 2005/0048768 A1
(43) Pub. Date: Mar. 3, 2005

(54) Apparatus and method for forming interconnects

(76) Inventors: Hiroaki Inoue, Tokyo (JP); Yukio Fukunaga, Tokyo (JP); Akira Susaki, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/924,767

(22) Filed: Aug. 25, 2004

(30) Foreign Application Priority Data
Aug. 26, 2003 (JP) 2003-208805
Oct. 3, 2003 (JP) 2003-345908

(51) Int. Cl. H01L 21/4763

(52) U.S. Cl. 438/629; 438/627; 438/624

(57) ABSTRACT

There is provided an apparatus for forming interconnects which can form embedded interconnects or interconnects protected with a protective film while preventing the formation of an oxide film. An interconnects-forming apparatus for forming embedded interconnects in a surface of a substrate, includes: a barrier layer-forming apparatus for forming a barrier layer on a surface of a substrate; a metal layer-forming apparatus for forming a metal layer on the surface of the barrier layer formed in the barrier layer-forming apparatus; and an apparatus frame capable of controlling the internal atmosphere; wherein the barrier layer-forming apparatus and the metal layer-forming apparatus are disposed in the apparatus frame.

### BACKGROUND OF THE INVENTION

1. Field of the Invention

The present invention relates to an apparatus and a method for forming interconnects, and more particularly to an apparatus and a method useful for forming embedded interconnects on a substrate such as a semiconductor wafer by filling a conductive material, such as copper, silver, or the like, in fine recesses for interconnects formed in a surface of the substrate, and furthermore for forming interconnects having a multi-level interconnect structure by covering surfaces of the embedded interconnects with a protective film.

2. Description of the Related Art

As an interconnect formation process for semiconductor devices, there is getting employed a process (so-called damascene process) in which an interconnect material (metal) is embedded in interconnect recesses such as trenches or contact holes. This process includes embedding aluminum or, recently, metal such as copper or silver in trenches or via holes, which have previously been formed in an interlevel dielectric layer, and then removing excessive metal by chemical mechanical polishing (CMP) for planarization.

With a recent trend toward finer intercconects of the semiconductor device, it is proposed to form a barrier layer of e.g. TaN on a surface of a substrate, and then to form a copper seed layer as a feeding layer for electroplating by depositing an interconnect material, such as copper, on a surface of the barrier layer directly by electroplating or the like, to embed the interconnect material.

In a case of interconnects formed by such a process, for example copper interconnects formed by using copper as an interconnect material, embedded copper interconnects have exposed surfaces after the flattening processing. In order to prevent thermal diffusion of such interconnects (copper), or to prevent oxidation of such interconnects (copper) e.g. during forming thereon an insulating film (oxide film) under an oxidizing atmosphere later to produce a semiconductor device having a multi-level interconnect structure, it is now under study to selectively cover the exposed surfaces of interconnects with an protective film (cap material) composed of a Co alloy, a Ni alloy or the like, such as CoWB, CoWP or the like, so as to prevent thermal diffusion and oxidation of the interconnects. Such a protective film of a Co alloy, a Ni alloy or the like can be produced e.g. by performing electroless plating. An interlevel barrier layer is formed on a surface of the substrate on which the protective film have been formed, then upper-level interconnects is formed on the interlevel barrier layer.

FIGS. 1A through 1D illustrate an example of forming copper interconnects in a semiconductor device. As shown in FIG. 1A, an insulating film (interlevel dielectric layer) 2, such as an oxide film of SiO₂ or a film of low-k material, is deposited on a conductive layer 1a formed on a semiconductor base 1 having formed semiconductor devices. Contact holes 3 and trenches 4 are formed in the insulating film 2 by performing a lithography/etching technique so as to provide fine recesses for interconnects. Thereafter, a barrier layer 5 of TaN or the like is formed on the insulating film 2, and a seed layer 6 as a feeding layer for electroplating is formed on the barrier layer 5 by sputtering or the like.

Then, as shown in FIG. 1B, copper plating is performed on a surface of a substrate W to fill the contact holes 3 and the trenches 4 with copper and, at the same time, deposit a copper layer 7 on the insulating film 2. Thereafter, the barrier layer 5, the seed layer 6 and the copper layer 7 on the insulating film 2 are removed by chemical mechanical polishing (CMP) or the like so as to leave copper filled in the contact holes 3 and the trenches 4, and have a surface of the insulating film 2 lie substantially on the same plane as this copper. Interconnects (copper interconnects) 8 composed of the seed layer 6 and the copper layer 7 are thus formed in the insulating film 2 as shown in FIG. 1C.

Then, as shown in FIG. 1D, electroless plating is performed on a surface of the substrate W to selectively form a protective film 9 of a Co alloy on surfaces of the interconnects 8, thereby covering and protecting the surfaces of the interconnects 8 with the protective film 9.

When the barrier layer 5, the seed layer 6 and the copper layer 7 on the insulating film (interlevel dielectric layer) 2 are removed into a flat surface by chemical-mechanical polishing (CMP) or the like to form interconnects 8 of copper in the above-described manner, a copper residue 7a remains on the surface of the insulating film 2 and a thin copper oxide film 8a is formed in the outermost surfaces of interconnects 8, as shown in FIG. 2A. The depth of the copper oxide film 8a is not uniform over the entire surfaces of interconnects 8 due to a difference in the oxidization speed which is caused by a difference in the crystal orientation of copper constituting the interconnects 8, for example, a difference in the oxidization speed between copper with crystal orientation (111) and copper with crystal orientation (100). Thus, there is variation (non-uniformity) in the thickness of the copper oxide film 8a formed in the outermost surfaces of the interconnects 8.

When forming the protective film 9 by electroless plating on the surfaces of interconnects 8 with the copper residue 7a remaining on the surface of insulating film 2 and the copper oxide film 8a formed in the outermost surfaces of interconnects 8, the protective film material grows on the copper residue 7a with the copper residue 7a as a nucleus, thus worsening the selectivity of the protective film 9. Furthermore, the adhesion between the interconnects 8 and the protective film 9 becomes poor, lowering the reliability of the interconnects 8 and the protective film 9.

It is, therefore, practiced to carry out a pre-electroless plating processing (cleaning processing) by immersing a substrate in, for example, an aqueous solution containing 0.5 g/L of H₂SO₄ for about one minute, thereby etching away the copper residue 7a remaining on the surface of insulating film 2 and the copper oxide film 8a formed in the outermost surfaces of interconnects 8, as shown in FIG. 2B, followed by electroless plating to form a protective film 9 of a Co alloy selectively on the exposed surfaces of interconnects 8, as shown in FIG. 2C.

As described above, however, the thickness of the copper oxide film 8a, formed in the outermost surfaces of interconnects 8 which have been flattened by polishing such as CMP, varies due to the crystal orientation of copper. Thus, when the copper oxide film 8a is etched away, the etching amount varies accordingly and irregularities are formed on the surfaces of interconnects 8 which become the underlying metal of electroless plating. Accordingly, when the protective film 9 is formed on the interconnects 8, marked irregularities are formed also on the surfaces of the protective film 9, resulting in poor contact of the surfaces with upper-layer interconnects and undulation of the surface of an interlevel dielectric layer which is formed in the next process step. Further, the volume of interconnects 8 decreases, whereby the interconnect resistance increases undesirably. In addition, it is generally difficult to completely remove the copper residue 7a from the surface of the insulating film 2 by etching.

Further, when carrying out the above-described pre-electroless plating processing (cleaning processing) to there by etch away the copper oxide film 8a formed in the outermost surfaces of the interconnects 8, the inner surface at the top portion of the sidewall of the barrier layer 5 becomes exposed. Since the pretreatment is carried out under atmospheric pressure using a solution in which dissolved oxygen is present, an oxide film 5a of the barrier layer 5, for example, a Ta oxide film in the case where the barrier layer 5 is composed of TaN, is formed in the inner surface of the exposed barrier layer 5 FIGS. 3 and 4 show the results of energy diffusive X-ray diffraction (EDX) analysis respectively at the points A and B of FIG. 2B, as observed when using TaN as the barrier layer 5, carrying out the pre-plating processing (cleaning processing) in the above-described manner, and forming a protective film of CoWB. The analytical data indicates the formation of a Ta oxide film at the point B of FIG. 2B. It is noted that Mo appearing in the analytical data is due to a holder (mesh) of the sample.

The formation of the oxide film 5a in the inner surface at the top portion of the sidewall of the barrier layer 5 lowers the reliability of the interconnects 8 of copper.

Wet plating, such as electroless plating, which is employed for directly forming a seed layer on the surface of a barrier layer or for selectively forming a protective film on the exposed surfaces of interconnects, as described above, is generally carried out in the air. Accordingly, such wet plating involves the formation of an oxide film at the interface between the barrier layer and the seed layer or at the interface between the protective film and an interlevel barrier layer, and the formation of such an oxide film is becoming a problem.

For example, as shown in FIG. 5, when forming a barrier layer 202 of TaN on a surface of a silicon substrate 200, removing an oxide film in a surface of the barrier layer 202 by wet processing, imparting a catalyst to the surface of the barrier layer 202, and forming a copper layer 204 by electroless plating, an oxide film 202a of the metal constituting the barrier layer 202 is formed at the interface between the barrier layer 202 and the copper layer 204 (in the surface of the barrier layer 202). Thus, even though the oxide film in the surface of the barrier layer 202 is removed by wet processing, the oxide film 202a is again formed in the surface of the barrier layer 202 during electroless plating because it is carried out in the air.

In another case, as shown in FIG. 6, interconnect trenches 208 are formed in an insulating film (interlevel dielectric layer) 206 of SiO₂ or the like deposited on the surface of a silicon substrate or the like, a barrier layer 210 of TaN or the like is formed on the surface, copper is embedded into the interconnect trenches 208, followed by CMP to flatten the surface, thereby forming copper interconnects 214 in the interlevel dielectric layer 206. A protective film (cap material) 216 of a CoWP alloy is then formed by electroless plating on the surfaces of the copper interconnects 214 to protect the interconnects 214, and an interlevel barrier layer 218 of SiN or the like is formed on the surface. When forming the interlevel barrier layer 218, because Co can be oxidized easily, a Co oxide film 216a is formed in the outmost surface of the protective film 216 (Co alloy film).

The presence of such an oxide film at the interface between a barrier layer and a seed layer (in the surface of the barrier layer) or the interface between a protective film and an interlevel barrier layer (in the surface of the protective film) makes the adhesion between the barrier layer and the seed layer (interconnects) or the adhesion between the protective film and the interlevel barrier layer insufficient, thus lowering the reliability of the interconnects or the protective film.

### SUMMARY OF THE INVENTION

The present invention has been made in view of the above situation in the related art. It is therefore a first object of the present invention to provide an apparatus for forming interconnects which can form embedded interconnects or interconnects protected with a protective film while preventing the formation of an oxide film.

It is a second object of the present invention to provide a method and an apparatus for forming interconnects which can form a protective film having a flat surface with good selectivity on the surfaces of interconnects without decreasing the volume of the interconnects, and can prevent the formation an oxide film in the surface of a barrier layer when forming the protective film.

In order to achieve the above objects, the present invention provides an interconnects-forming apparatus for forming embedded interconnects in a surface of a substrate, comprising: a barrier layer-forming apparatus for forming a barrier layer on a surface of a substrate; a metal layer-forming apparatus for forming a metal layer on a surface of the barrier layer formed in the barrier layer-forming apparatus; and an apparatus frame capable of controlling the internal atmosphere; wherein the barrier layer-forming apparatus and the metal layer-forming apparatus are disposed in the apparatus frame.

According to this interconnects-forming apparatus, a series of process steps of forming a barrier layer on a surface of a substrate, and forming a metal layer, such as a seed layer, on a surface of the barrier layer, are carried out in a controlled atmosphere in the apparatus frame without being exposed to an oxidizing atmosphere as in the air. This makes it possible to form the metal layer, such as a seed layer, on the surface of the barrier layer while preventing the formation of an oxide film in the surface of the barrier layer.

The metal layer is, for example, a seed layer or an interconnect layer.

The barrier layer-forming apparatus and/or the metal layer-forming apparatus preferably includes a processing chamber capable of controlling the internal atmosphere.

This makes it possible, for example, to form a barrier layer by CVD or PVD in a vacuum atmosphere and form a metal layer, such as a seed layer, by wet plating in an inert gas atmosphere, respectively.

It is preferred that the substrate, which is carried in the apparatus frame, have an interlevel dielectric layer which has been formed by PVD, CVD or a wet coating method, and an interconnect pattern which has been formed in the interlevel dielectric layer by RIE, CDE, sputter etching or wet etching.

The barrier layer-forming apparatus is comprised of, for example, a PVD apparatus, a CVD apparatus or a wet plating apparatus.

The metal layer-forming apparatus is preferably comprised of a wet plating apparatus.

According to the interconnects-forming apparatus, a metal layer, such as a seed layer or an interconnect layer, can be formed on a surface of a barrier layer by wet plating, such as electroless plating, stably at a low cost while preventing the formation of an oxide film in the surface of the barrier layer.

The wet plating apparatus preferably uses a liquid having a dissolved oxygen concentration of not more than 5 ppb as a processing liquid.

By thus using a liquid having a dissolved oxygen concentration of not more than 5 ppb as a processing liquid, such as a plating solution or a cleaning water, in the wet plating apparatus, when forming a metal layer such as a seed layer on the surface of a barrier layer by wet plating, such as electroless plating, oxidation of the surface of the barrier layer due to oxygen contained in the processing liquid can be prevented.

Preferably, the wet plating apparatus is designed to remove a solution adhering to the substrate by scattering the solution with an inert gas.

This makes it possible to remove a solution, such as a pretreatment solution which has adhered to a substrate upon pre-treating, quickly after the pre-treating so as to prevent a barrier layer from being oxidized by the solution which would otherwise remain on the substrate.

The present invention also provides another interconnects-forming apparatus for forming embedded interconnects in a surface of a substrate, comprising: a flattening apparatus for removing an extra metal film formed on a surface of a substrate and flattening the surface of the substrate; a protective film-forming apparatus for forming a protective film selectively on the exposed surfaces of embedded interconnects which has been exposed by the flattening; and an apparatus frame capable of controlling the internal atmosphere; wherein the flattening apparatus and the protective film-forming apparatus are disposed in the apparatus frame.

According to this interconnects-forming apparatus, a series of process steps of flattening a surface of a substrate and forming a protective film selectively on the exposed surfaces of embedded interconnects which have been exposed by the flattening, are carried out in a controlled atmosphere in the apparatus frame without being exposed to an oxidizing atmosphere as in the air. This makes it possible to form the protective film on the surfaces of embedded interconnects while preventing the formation of an oxide film in the surfaces of embedded interconnects.

The flattening apparatus and/or the protective film-forming apparatus preferably includes a processing chamber capable of controlling the internal atmosphere.

The flattening apparatus is comprised of, for example, a CMP apparatus or a wet polishing apparatus.

The present invention also provides still another interconnects-forming apparatus for forming embedded interconnects in a surface of a substrate, comprising: a protective film-forming apparatus for forming a protective film selectively on the exposed surfaces of embedded interconnects; an interlevel barrier layer-forming apparatus for forming an interlevel barrier layer on a surface of a substrate having the thus-formed protective film; and an apparatus frame capable of controlling the internal atmosphere; wherein the protective film-forming apparatus and the interlevel barrier layer-forming apparatus are disposed in the apparatus frame.

According to this interconnects-forming apparatus, a series of process steps of forming a protective film selectively on the exposed surfaces of embedded interconnects, and forming an interlevel barrier layer on the surface of the substrate having the thus-formed protective film are carried out in a controlled atmosphere in the apparatus frame without being exposed to an oxidizing atmosphere as in the air. This makes it possible to form the interlevel barrier layer on the surface of the substrate while preventing the formation of an oxide film in the surface of the protective film.

The protective film-forming apparatus and/or the interlevel barrier layer-forming apparatus preferably includes a processing chamber capable of controlling the internal atmosphere.

The protective film-forming apparatus is preferably comprised of a wet plating apparatus.

According to the interconnects-forming apparatus, an interlevel barrier layer can be formed on a surface of a substrate while preventing oxidation of a protective film which has been formed by wet plating, such as electroless plating, even when a Co alloy which can be easily oxidized is employed as the protective film.

In a preferred embodiment of the present invention, a transport device for transporting the substrate between the apparatuses is disposed in the apparatus frame.

This can prevent a substrate from being exposed to an oxidizing atmosphere, such as the air, and oxidized during transportation of the substrate.

In a preferred embodiment of the present invention, the interior of the apparatus frame is kept in a vacuum atmosphere or an inert gas atmosphere.

The inert gas atmosphere is, for example, a N₂ gas atmosphere. The pressure of inert gas in the apparatus frame may be made higher than atmospheric pressure (positive pressure), thereby preventing the air from flowing into the apparatus frame.

In a preferred embodiment of the present invention, the interconnects-forming apparatus further comprises in the apparatus frame an embedding apparatus for embedding an interconnect material into interconnect recesses provided in the surface of the substrate.

The embedding apparatus is comprised of, for example, a PVD apparatus, a CVD apparatus or a wet plating apparatus.

In a preferred embodiment of the present invention, the interconnects-forming apparatus further comprises in the flame apparatus a heat treatment apparatus for heat-treating the interconnect material embedded in the interconnect recesses.

The present invention also provides a method for forming interconnects, comprising: embedding an interconnect material into interconnect recesses formed in an insulating film formed on a substrate; removing an extra interconnect material on the insulating film and flattening the surface, thereby forming interconnects in the interconnect recesses; reducing an oxide film in the outermost surfaces of the interconnects; and forming a protective film selectively on the reduced surfaces of the interconnects by electroless plating.

By reducing an oxide film in the outermost surfaces of interconnects to thereby return to the original non-oxidized metal state having no oxide film in the outermost surfaces of interconnects, there is no need to etch away the oxide film. This can avoid the decrease in volume of interconnects, thereby avoiding a rise in the interconnect resistance. Further, there is no exposure of a barrier layer associated with etching of the oxide film. Accordingly, there is no fear of the formation of an oxide film in the surface of the barrier layer before a protective film is formed by electroless plating. Further, the flattened surfaces of interconnects after polishing, such as CMP, can be kept as they are. Accordingly, a protective film having a flat surface can be formed selectively by electroless plating on the flat surfaces of interconnects.

Preferably, the oxide film in the outermost surfaces of the interconnects is reduced by wet processing with a reducing solution.

The oxide film in the outermost surfaces of interconnects can be reduced, for example, by immersing the substrate in a reducing solution or spraying a reducing solution onto the surface of a substrate.

The reducing solution is, for example, a solution containing an alkylamine borane or a borohydride compound, or a cathode water. The cathode water is, for example, water containing the below-described active hydrogen.

It is also possible to reduce the oxide film in the outermost surfaces of the interconnects by dry processing in an active hydrogen-containing atmosphere.

The active hydrogen refers to hydrogen in the atomic state which is liable to cause chemical reaction, produced through breakage of the stable covalent bond of hydrogen molecule by electric discharge, high-temperature heating, ultraviolet rays, etc. For example, an oxide film in the outermost surfaces of interconnects can be reduced by placing the substrate in a processing chamber whose interior is kept in an atmosphere containing an active hydrogen (hydrogen radical).

The active hydrogen-containing atmosphere is, for example, a H₂ plasma atmosphere or a NH₃ plasma atmosphere.

Preferably, the interconnect material embedded in the interconnect recesses is subjected to heat treatment.

Preferably, after the formation of the protective film by electroless plating, a residue, which has not been removed by the flattening step and remains on the surface of the insulating film and on which the protective film material has been grown by the electroless plating, is removed.

By removing a residue remaining un-removed on the surface of the insulating film after growing the protective film material on the residue and thereby making the residue larger, the residue can be removed easily and securely, whereby the selectivity of the protective film can be enhanced.

The residue on which the protective film material has been grown is removed preferably by mechanically peeling the residue from the surface of the insulating film.

The residue on which the protective film material has been grown is a mere deposit having no chemical bond to the insulating film, and therefore it can be peeled from the surface of the insulating film easily and securely, for example, by scrub cleaning with a roll sponge. It has been confirmed that such a very small amount of residue that is not detachable with AES but only detectable with TOF-SIMS can be removed by scrub cleaning.

In contrast, the protective film formed on the surfaces of interconnects has a metallic bond to the interconnects, and therefore will not be peeled off by scrub cleaning or the like.

The interconnect material is, for example, Cu, a Cu alloy, Au, an Au alloy, W, or a W alloy.

The protective film is, for example, Co, a Co alloy, Ni, or a Ni alloy.

The present invention also provides still another interconnects-forming apparatus comprising: a flattening apparatus for removing an extra interconnect material on an insulating film which is formed on a substrate and in which interconnect recesses are formed, and flattening the surface, thereby forming interconnects in the interconnect recesses; a reduction apparatus for reducing an oxide film in the outermost surfaces of the interconnects; and an electroless plating apparatus for forming a protective film selectively on the reduced surfaces of the interconnects.

The present invention also provides still another interconnects-forming apparatus comprising: an embedding apparatus for embedding an interconnect material into interconnect recesses formed in an insulating film formed on a substrate; a flattening apparatus for removing an extra interconnect material on the insulating film and flattening the surface, thereby forming interconnects in the interconnect recesses; a reduction apparatus for reducing an oxide film in the outermost surfaces of the interconnects; and an electroless plating apparatus for forming a protective film selectively on the reduced surfaces of the interconnects by electroless plating.

In a preferred embodiment of the present invention, the reduction apparatus and the electroless plating apparatus are disposed in an apparatus frame capable of controlling the internal atmosphere.

By making the internal atmosphere of the apparatus frame an inert gas atmosphere, for example, a N₂ gas atmosphere so that a substrate, after an oxide film in the outermost surfaces of the interconnects is reduced, will not be exposed to the air, an oxide film can be prevented from being formed again in the outermost surfaces of the interconnects.

The reduction apparatus is preferably designed to remove a solution adhering to the substrate by scattering the solution with an inert gas.

The processing liquid, which has been used for the reduction of an oxide film in the outermost surfaces of interconnects and is adhering to the substrate surface, is removed without carrying out water-cleaning using e.g. pure water containing dissolved oxygen. This can avoid re-formation of an oxide film in the outermost surfaces of interconnects upon removal of the processing liquid.

In a preferred embodiment of the present invention, the interconnects-forming apparatus further comprises a residue removal apparatus for removing a residue which has not been removed by the flattening and remains on the surface of the insulating film and on which the protective film material has been grown by electroless plating.

The residue removal apparatus is comprised of, for example, a scrub cleaning apparatus.

In a preferred embodiment of the present invention, the interconnects-forming apparatus further comprises a heat treatment apparatus for heat-treating the interconnect material embedded in the interconnect recesses.

The above and other objects, features, and advantages of the present invention will be apparent from the following description when taken in conjunction with the accompanying drawings which illustrates preferred embodiments of the present invention by way of example.

### BRIEF DESCRIPTION OF THE DRAWINGS

FIGS. 1A through 1D are diagrams illustrating, in sequence of process steps, an example of the formation of copper interconnects;

FIGS. 2A through 2C are diagrams illustrating, in sequence of process steps, processes after flattening in a conventional method for forming interconnects;

FIG. 3 is a chart showing the results of EDX (energy dispersive X-ray) diffraction analysis at the point A shown in FIG. 2B;

FIG. 4 is a chart showing the results of EDX (energy dispersive X-ray) diffraction analysis at the point B shown in FIG. 2B;

FIG. 5 is a diagram schematically showing a TEM (transmission electron microscope) image of the sample of Comp. Example 1, including the interface between a barrier layer and a copper layer;

FIG. 6 is a diagram schematically showing a TEM (transmission electron microscope) image of the sample of Comp. Example 2, including the interface between a protective film and an interlevel barrier layer;

FIG. 7 is a plan view showing the overall construction of an interconnects-forming apparatus according to an embodiment of the present invention;

FIG. 8 is an enlarged schematic view of the barrier layer-forming apparatus of the interconnects-forming apparatus shown in FIG. 7;

FIG. 9 is a flow chart of a process for forming interconnects by the interconnects-forming apparatus shown in FIG. 7;

FIG. 10 is a schematic diagram illustrating the formation of an interconnect pattern in an interlevel dielectric layer of a substrate;

FIG. 11 is a schematic diagram illustrating the formation of a barrier layer on the surface of the substrate shown in FIG. 10;

FIG. 12 is a schematic diagram illustrating the formation of a seed layer on the surface of the barrier layer of the substrate shown in FIG. 10;

FIG. 13 is a schematic diagram illustrating the embedding of copper by copper plating of the surface of the substrate shown in FIG. 12;

FIG. 14 is a schematic diagram illustrating flattening of the surface of the substrate shown in FIG. 13;

FIG. 15 is a schematic diagram illustrating the selective formation of a protective film on the surfaces of the interconnects of the substrate shown in FIG. 14;

FIG. 16 is a schematic diagram illustrating the formation of an interlevel barrier layer on the surface of the substrate shown in FIG. 15;

FIG. 17 is a diagram schematically showing a TEM (transmission electron microscope) image of the sample of Example 1, including the interface between a barrier layer and a copper layer;

FIG. 18 is a diagram schematically showing a TEM (transmission electron microscope) image of the sample of Example 2, including the interface between a protective film and an interlevel barrier layer;

FIG. 19 is a plan view showing the overall construction of an interconnects-forming apparatus according to another embodiment of the present invention;

FIG. 20 is a schematic view of the processing section of the reduction apparatus shown in FIG. 19;

FIG. 21 is a flow chart of a process for forming interconnects by the interconnects-forming apparatus shown in FIG. 19;

FIGS. 22A through 22D are diagrams illustrating, in sequence of process steps, processes after flattening in a method for forming interconnects according to an embodiment of the present invention; and

FIGS. 23A through 23C are diagrams schematically showing TOF-SIMS ion images of the samples of Example 3.

### DETAILED DESCRIPTION OF THE PREFERRED EMBODIMENTS

Preferred embodiments of the present invention will now be described in detail with reference to the drawings. The following description illustrates the case of forming interconnects of copper (copper interconnects) on a substrate such as a semiconductor wafer, and forming a protective film of a CoWP or CoWB alloy selectively on the surfaces of the interconnects to protect the interconnects.

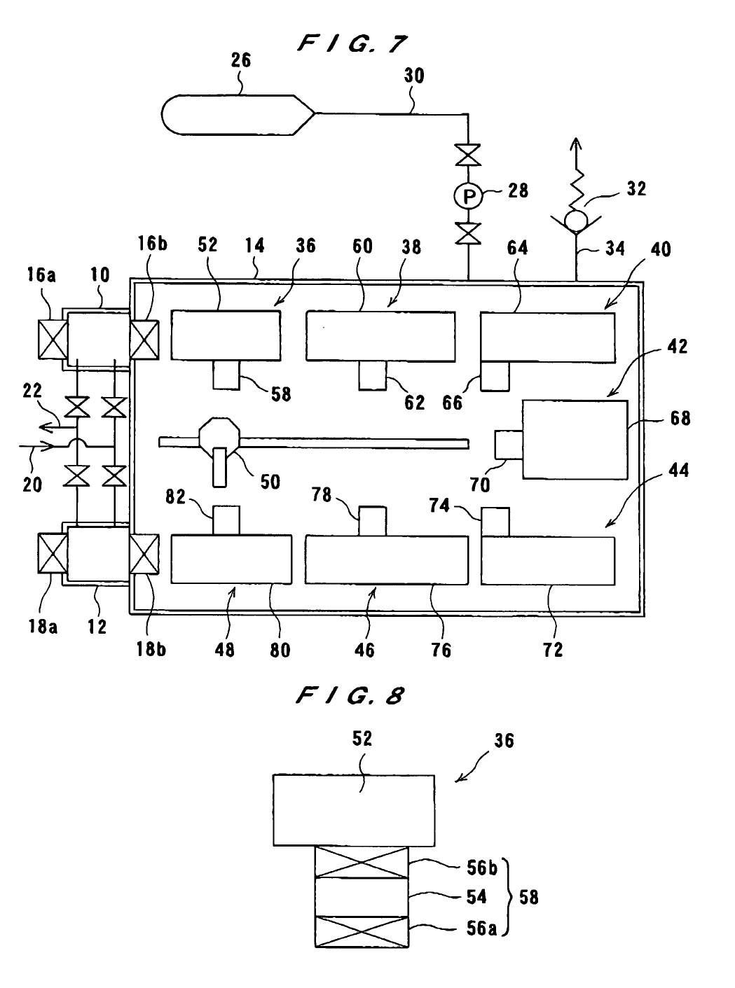

FIG. 7 shows an overall layout plan of an interconnects-forming apparatus according to an embodiment of the present invention. As shown in FIG. 7, the interconnects-forming apparatus includes a loading chamber 10 for carrying in a cassette housing substrates and carrying out an empty cassette, an unloading chamber 12 for carrying in an empty cassette and carrying out a cassette housing substrates after a series of processes, and a rectangular apparatus frame 14 communicating with the loading chamber 10 and with the unloading chamber 12.

A pair of gate valves 16a, 16b is provided at the inlet of the loading chamber 10 and at the outlet on the apparatus frame side. Similarly, a pair of gate valves 18a, 18b is provided at the inlet of the unloading chamber 12 and at the outlet on the apparatus frame side. An inert gas supply line 20 and a gas discharge line 22 are connected to the loading chamber 10 and also to the unloading chamber 12. Supply and discharge of gas for the loading chamber 10 and for the unloading chamber 12 can be performed independently by shut-off valves.

The apparatus frame 14 is designed to be hermetically closable, and is connected to an inert gas supply line 30 extending from an inert gas supply source 26 and having, interposed therein, a gas supply pump 28 and a pair of shut-off valves disposed on either side of the pump 28, and is also connected to a gas discharge line 34 having, interposed therein, a gas discharge valve 32 that opens at a predetermined pressure higher than atmospheric pressure. Thus, by the actuation of the gas supply pump 28, an inert gas such as N₂ gas is supplied into the apparatus frame 14, and the gas discharge valve 32 of the gas discharge line 34 opens when the pressure in the apparatus frame 14 has reached a predetermined pressure higher than atmospheric pressure, so that the interior of the apparatus frame 14 can be kept in the inert gas atmosphere at the predetermined pressure high than atmospheric pressure.

By thus keeping the pressure in the interior of the apparatus frame 14 at a higher pressure (positive pressure) than atmospheric pressure, the air can be prevented from flowing into the apparatus frame 14 with the inert gas internal atmosphere.

In the interior of the apparatus frame 14 are housed a barrier layer-forming apparatus 36, a seed layer-forming apparatus 38 as a metal layer-forming apparatus, an embedding apparatus 40, a heat treatment apparatus 42, a flattening apparatus 44, a protective film-forming apparatus 46, and an interlevel barrier layer-forming apparatus 48, which are disposed along a substrate transport route. A movable transport robot 50 as a transport device is disposed in a position surrounded by these apparatuses.

The barrier layer-forming apparatus 36 is to form a barrier layer of TaN or the like on a surface of a substrate and, according to this embodiment, is comprised of a sputtering apparatus as shown in FIG. 8, including a processing chamber 52 capable of vacuum evacuation, and an atmosphere adjustment mechanism 58 having a load lock chamber 54 partitioned by a pair of gate valves 56a, 56b. The barrier layer-forming apparatus 36 may be comprised of an apparatus other than a sputtering apparatus, such as a PVD apparatus, a CVD apparatus or a wet plating apparatus.

The seed layer-forming apparatus (metal layer-forming apparatus) 38 is to form a seed layer, such as a copper seed layer, on the surface of the barrier layer which has been formed on the surface of the substrate by the barrier layer-forming apparatus 36 and, according to this embodiment, is comprised of an electroless plating apparatus which includes a processing chamber 60 capable of replacing the internal atmosphere with an inert gas atmosphere such as N₂ gas, and an atmosphere adjustment mechanism 62 having the same construction as the above-described atmosphere adjustment mechanism 58 of the barrier layer-forming apparatus (sputtering apparatus) 36. The electroless plating apparatus (seed layer-forming apparatus) 38 also include in the processing chamber 60 not-shown pretreatment tank, plating tank and post-treatment tank. A series of electroless plating processes comprising: cleaning processing (chemical cleaning) of the surface of the barrier layer and/or pretreatment of the substrate, such as a catalyst-imparting treatment, in the pretreatment tank; electroless plating in the plating tank; and post-plating processing, such as cleaning, in the post-treatment tank, can be carried out successively in an inert gas atmosphere, such as a N₂ gas atmosphere.

Various processing liquids, such as a pretreatment liquid (liquid chemical), a plating solution and a cleaning water are used in the electroless plating apparatus (seed layer-forming apparatus) 38, and the processing liquids all contain dissolve oxygen in a concentration of not more than 5 ppb. By thus using a liquid having a dissolved oxygen concentration of not more than 5 ppb as a processing liquid, such as a plating solution or a cleaning water, when forming a seed layer on the surface of a barrier layer by electroless plating, oxidation of the surface of the barrier layer due to oxygen contained in the processing liquid can be prevented.

Further, the electroless plating apparatus (seed layer-forming apparatus) 38 is designed to remove (blow off) a solution adhering to a substrate by scattering the solution with an inert gas. This makes it possible to quickly remove a solution, such as a pretreatment solution, which has adhered to a substrate upon pre-treating, so as to prevent possible oxidation of the barrier layer by the solution which would otherwise remain on the substrate.

The embedding apparatus 40 is to perform plating of the surface of the substrate for embedding of an interconnect material, such as copper, in interconnect recesses, such as interconnect trenches and via holes, formed in the substrate and, according to this embodiment, is comprised of an electroplating apparatus which includes a processing chamber 64 capable of replacing the internal atmosphere with an inert gas atmosphere such as N₂ gas, and an atmosphere adjustment mechanism 66 having the same construction as the above-described atmosphere adjustment mechanism 58 of the barrier layer-forming apparatus (sputtering apparatus) 36. AS with the above-described electroless plating apparatus (seed layer-forming apparatus) 38, the electroplating apparatus (embedding apparatus) 40 also includes in the processing chamber 64 a plating tank and optionally a pretreatment tank and a post-treatment tank.

The embedding apparatus 40 may also be comprised of an electroless plating apparatus, a PVD apparatus or a CVD apparatus.

According to this embodiment, the seed layer-forming apparatus 38 as a metal layer-forming apparatus and the embedding apparatus 40 are provided, and the formation of a seed layer by the seed layer-forming apparatus (electroless plating apparatus) 38 and the embedding of an interconnect material (formation of interconnect layer) by the embedding apparatus (electroplating apparatus) 40 are carried out separately. However, it is also possible to use an electroless plating apparatus, for example, having the same construction as described above, as a metal layer-forming apparatus, and carry out e.g. copper plating directly onto the surface of a barrier layer by the metal layer-forming apparatus (electroless plating apparatus), thereby forming an interconnect layer.

The heat treatment apparatus 42 is to carry out heat treatment (annealing) e.g. at 100-600° C. of the interconnect material (copper layer) formed in the embedding apparatus 40 and, according to this embodiment, is comprised of a lamp annealing apparatus which includes a processing chamber (lamp annealing oven) 68 capable of replacing the internal atmosphere with an inert gas atmosphere such as N₂ gas, and an atmosphere adjustment mechanism 70 having the same construction as the above-described atmosphere adjustment mechanism 58 of the barrier layer-forming apparatus (sputtering apparatus) 36. The heat treatment apparatus 42 may also be comprised of an apparatus including a radiation heat oven, a reflected heat oven, a hot plate oven or a heat convection oven.

The flattening apparatus 44 is to remove an extra interconnect material which was formed on the surface of the substrate upon the embedding of the interconnect material in the embedding apparatus 40 and flatten the surface of the substrate so as to make the surface of an insulating film (interlevel dielectric layer) flush with the surface of the interconnect material such as copper embedded in the interconnect trenches and via holes and, according to this embodiment, is comprised of a CMP (chemical-mechanical polishing) apparatus which includes a processing chamber 72 capable of replacing the internal atmosphere with an inert gas atmosphere such as N₂ gas, and an atmosphere adjustment mechanism 74 having the same construction as the above-described atmosphere adjustment mechanism 58 of the barrier layer-forming apparatus (sputtering apparatus) 36. The flattening apparatus 44 may also be comprised of a wet polishing apparatus.

The protective film-forming apparatus 46 is to form a protective film of a CoWP alloy or the like selectively on the surfaces of the interconnects (copper interconnects), which has been exposed on the surface of the substrate by the flattening in the flattening apparatus 44, to protect the interconnects and, according to this embodiment, is comprised of an electroless plating apparatus which, as with the above-described seed layer-forming apparatus 38, includes a processing chamber 76 capable of replacing the internal atmosphere with an inert gas atmosphere such as N₂ gas, and an atmosphere adjustment mechanism 78 having the same construction as the above-described atmosphere adjustment mechanism 58 of the barrier layer-forming apparatus (sputtering apparatus) 36. The electroless plating apparatus (protective film-forming apparatus) 46 also includes in the processing chamber 76 not-shown pretreatment tank, plating tank and post-treatment tank.

The interlevel barrier layer-forming apparatus 48 is to form an interlevel barrier layer of SiN or the like on the surface of the substrate after the selective formation of the protective film in the protective film-forming apparatus 46 and, according to this embodiment, is comprised of a CVD apparatus which includes a processing chamber 80 capable of vacuum evacuation, and an atmosphere adjustment mechanism 82 having the same construction as the above-described atmosphere adjustment mechanism 58 of the barrier layer-forming apparatus (sputtering apparatus) 36. The interlevel barrier layer-forming apparatus 48 may also be comprised of a PVD apparatus or a wet plating apparatus.

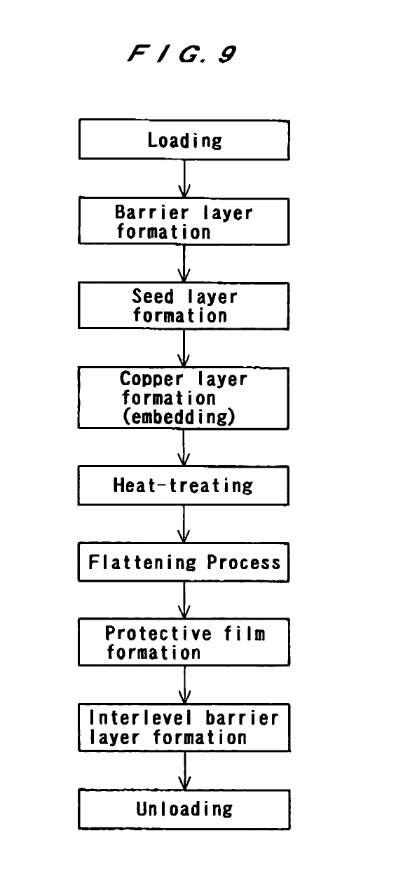

A series of process steps for forming interconnects by the interconnects-forming apparatus will now be described by referring to FIGS. 9 through 16.

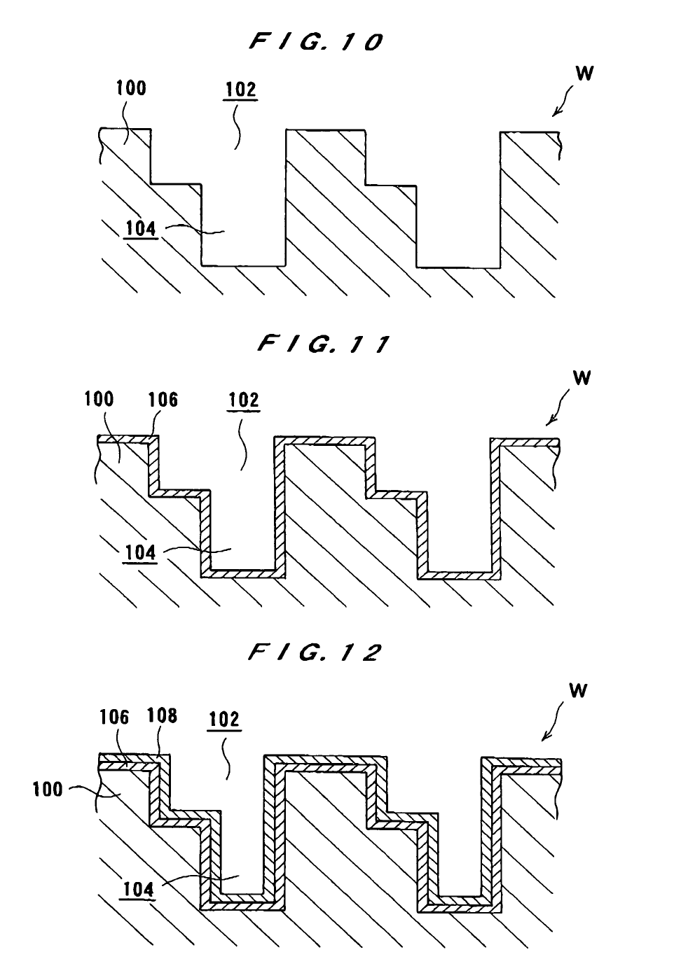

First, a substrate W is prepared by forming an interlevel dielectric layer (insulating film) 100 of SiO₂ or the like by, for example, PVD, CVD or a wet coating method, and then forming an interconnect pattern comprising interconnect recesses, such as interconnect trenches 102 and via holes 104, in the interlevel dielectric layer 100 by, for example, RIE, CDE, sputter etching or wet etching, as shown in FIG. 10. Such substrates W are housed in a cassette, and the cassette is carried in the loading chamber 10. At the same time, an empty cassette is carried in the unloading chamber 12. Thereafter, the internal atmosphere of each of the loading chamber 10 and the unloading chamber 12 is replaced with an inert gas atmosphere such as N₂ gas.

In particular, when the gate valves 16a, 18a on the inlet sides of the loading chamber 10 and the unloading chamber 12 are open while the gate valves 16b, 18b on the outlet sides are closed, the cassettes are carried in the loading chamber 10 and the unloading chamber 12. Thereafter, the gate valves 16a, 18a on the outlet sides are closed. While evacuating the loading chamber 10 and the unloading chamber 12 through the gas discharge line 22, an inert gas, such as N₂ gas, is supplied through the inert gas supply line 20 into the loading chamber 10 and the unloading chamber 12, thereby replacing the internal atmosphere of each of the loading chamber 10 and the unloading chamber 12 with the inert gas atmosphere at a higher pressure (positive pressure) than atmospheric pressure.

Similarly, while evacuating the apparatus frame 14 through the gas discharge line 34, an inert gas, such as N₂ gas, is supplied through the inert gas supply line 30 into the apparatus frame 14, thereby replacing the internal atmosphere of the apparatus frame 14 with the inert gas atmosphere at a higher pressure than atmospheric pressure. Thereafter, the gate valves 16b, 18b at the outlets on the apparatus frame 14 sides of the loading chamber 10 and the unloading chamber 12 are opened.

Next, the substrates W having the interconnect pattern are taken one by one by the transport robot 50 out of the cassette in the loading chamber 10, and the substrate W is carried in the barrier layer-forming apparatus (sputtering apparatus) 36. In the barrier layer-forming apparatus 36, by the atmosphere adjustment mechanism 58 comprising the load lock chamber 54 and the gate valves 56a, 56b, the substrate W is carried in the processing chamber 52 without breaking the vacuum in the processing chamber 52. In the vacuum chamber 52, as shown in FIG. 11, a barrier layer 106 of TaN or the like with a thickness of e.g. about 30 nm is formed by sputtering on the surface of the substrate W.

The substrate W having the thus-formed barrier layer 106 is carried in the processing chamber 60, which is kept in an inert gas (e.g. N₂ gas) atmosphere, of the seed layer-forming apparatus (electroless plating apparatus) 38 as a metal layer-forming apparatus. As necessary, the thickness of the barrier layer 106 is measured with a film thickness measuring device (not shown).

In the seed layer-forming apparatus 38, pretreatment of the substrate W, for example, a catalyst-imparting treatment for imparting a catalyst such as Pd to the surface of the substrate W, is carried out. The substrate W after the pretreatment is subjected to a series of electroless plating processes of: immersing the substrate W in an electroless copper-plating solution, held in a plating tank, e.g. at 60° C. for one minute; allowing the substrate surface after the plating to be in contact with a post-cleaning liquid in a post-cleaning tank to carry out post-cleaning of the substrate W; and rotating the cleaned substrate W at a high speed to spin-dry the substrate W. A seed layer 108 of copper with a thickness of e.g. 30 nm is thus formed on the surface of the barrier layer 106, as shown in FIG. 12.

By using a liquid having a dissolved oxygen concentration of not more than 5 ppb as a processing liquid, such as a plating solution or a cleaning water, when forming the seed layer 108 on the surface of the barrier layer 106 by electroless plating, oxidation of the surface of the barrier layer 106 due to oxygen contained in the processing liquid can be prevented. Further, by removing (blowing off) a solution adhering to the substrate W by scattering the solution with an inert gas, the solution, such as a pretreatment solution which has adhered to the substrate upon pretreatment, can be removed quickly so as to prevent possible oxidation of the barrier layer 106 by the solution which would otherwise remain on the substrate.

Next, the substrate W having the thus-formed seed layer 108 is carried in the processing chamber 64, whose interior is kept in an inert gas (e.g. N₂ gas) atmosphere, of the embedding apparatus (electroplating apparatus) 40. As necessary, the initial film thickness (thickness of the seed layer 108) is measured with a film thickness measuring device (not shown).

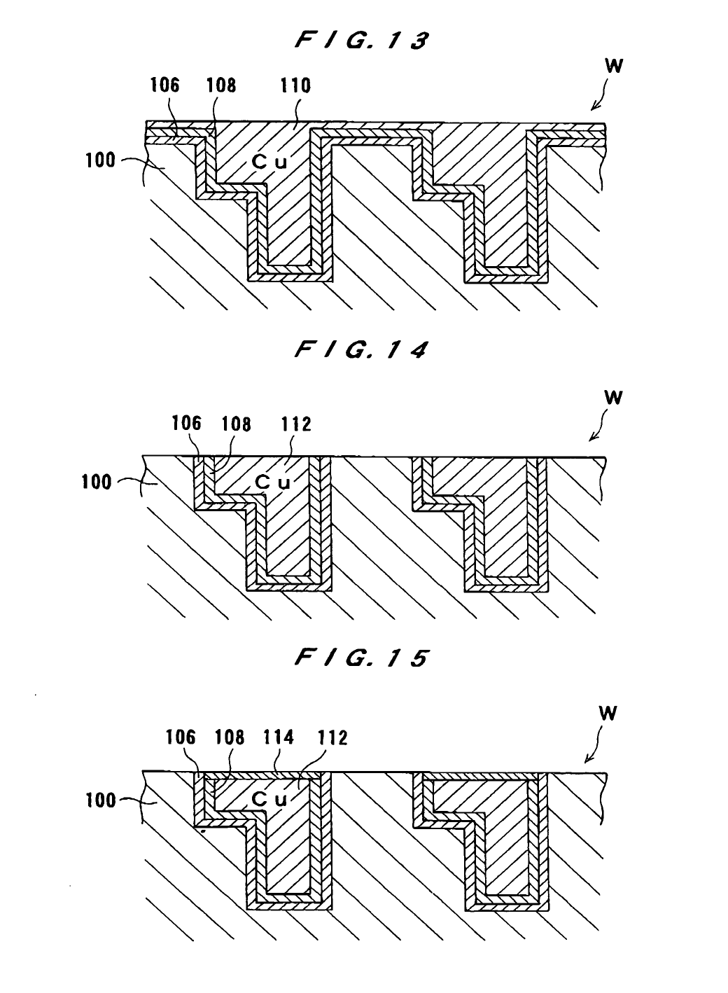

In the embedding apparatus 40, according to necessity, the seed layer 108 formed on the surface of the substrate is allowed to be in contact with a pretreatment liquid in a pretreatment tank to carry out pretreatment, such as hydrophilization processing or pro-cleaning, of the surface of the substrate W. Thereafter, the substrate after the pretreatment is immersed in an electrolytic copper-plating solution in a plating tank for e.g. 2.5 minutes while applying a plating current at e.g. 20 mA/cm², thereby depositing a copper layer 110 having a thickness of e.g. about 1000 nm on the surface of the substrate W and embedding copper into the interconnect trenches 102 and the via holes 104, as shown in FIG. 13. The substrate W after the plating is rotated at a high speed to spin-dry the substrate W.

It is also possible to use an electroless plating apparatus, for example, having the same construction as described above, as a metal layer-forming apparatus, and carry out copper plating directly onto the surface of the barrier layer 106 by the metal layer-forming apparatus (electroless plating apparatus), thereby forming the copper layer 110 as an interconnect layer.

The substrate W having the thus-formed copper layer 110 is carried in the processing chamber 68 of the heat treatment apparatus (lamp annealing apparatus) 42. In the heat treatment apparatus 42, the substrate W is subjected to heat-treating (lamp annealing), for example, at 350° C. for 5 minutes in a N₂ gas atmosphere.

The substrate W after the annealing is carried in the processing chamber 72, whose interior is kept in an inert gas (e.g. N₂ gas) atmosphere, of the flattening apparatus (CMP apparatus) 44. Before carrying in the processing chamber 72, the substrate W after the heat treatment may be transported to a film thickness measuring device to measure a film thickness of copper. The film thickness of the copper layer 110 can be determined by the difference between the measured film thickness and the above-described initial film thickness. Based on the film thickness of copper layer 110 thus determined, the plating time of the next substrate, for example, may be adjusted and, in case of a shortage of the film thickness, an additional copper layer formation by plating of the substrate W may be carried out.

In the flattening apparatus 44, as shown in FIG. 14, the unnecessary copper layer 110, seed layer 108 and barrier layer 106 deposited on the substrate W are polished and removed, and the surface of the substrate W is flattened, thereby forming interconnects of copper (copper interconnects) 112 in the interlevel dielectric layer 100. During polishing, the film thickness or the finish of the substrate may be checked with a monitor so that polishing may be terminated when the end point is detected with the monitor. The surface of the substrate W after the flattening is cleaned with a chemical and further cleaned (rinsed) with pure water, and the substrate W is then rotated at a high speed to spin-dry the substrate W.

The substrate W after the flattening is carried in the processing chamber 76, whose interior is kept in an inert gas (e.g. N₂ gas) atmosphere, of the protective film-forming apparatus (electroless plating apparatus) 46.

In the protective film-forming apparatus 46, pretreatments of the substrate W, including cleaning processing (CMP residue removal processing) of the surface of the copper layer 110 and a catalyst-imparting treatment for imparting a catalyst such as Pd to the surfaces of interconnects 112, are carried out by immersing the surface of the substrate in a pretreatment liquid in a pretreatment tank. The substrate W after the pretreatment is subjected to a series of electroless plating processes of: immersing the substrate W in an electroless CoWP-plating solution, held in a plating tank, e.g. at 80° C. for three minutes; allowing the surface of the substrate W after the plating to be in contact with a post-cleaning liquid in a post-cleaning tank to carry out post-cleaning of the substrate W; and rotating the cleaned substrate W at a high speed to spin-dry the substrate W. A protective film 114 of a CoWP alloy with a thickness of e.g. 20 nm is thus formed on the surfaces of the interconnects 112, formed in the interlevel dielectric layer 100, to protect the interconnects 112, as shown in FIG. 15. The thickness of the protective film 114 is generally about 0.1 to 500 nm, preferably about 1 to 200 nm, more preferably about 10 to 100 nm. During the electroless plating, the thickness of the protective film 114 may be monitored, and the electroless plating may be terminated when the film thickness has reached a predetermined value, i.e. when the end point is detected.

The substrate W having the thus-formed protective film 114 is carried in the processing chamber 80, whose interior is kept in a vacuum atmosphere, of the interlevel barrier layer-forming apparatus (CVD apparatus) 48. In the interlevel barrier layer-forming apparatus 48, as shown in FIG. 16, an interlevel barrier layer 116 of SiN or the like having a thickness of e.g. about 30 nm is formed under vacuum by CVD on the surface of the substrate W.

The substrate W having the thus-formed interlevel barrier layer 116 is carried by the transport robot 50 into the cassette in the unloading chamber 12.

Though in this embodiment copper is used as an interconnect material, it is also possible to use a copper alloy, silver or a silver alloy other than copper. Further, though a CoWP alloy is used for the protective film 114, it is also possible to use Co as a simple substance, or a Co alloy other than CoWP, such as a CoWB alloy, a CoP alloy or a CoB alloy. Furthermore, Ni as a simple substance, or a Ni alloy, such as a NiWP alloy, a NiWB alloy, a NiP alloy or a NiB alloy, may also be employed.

### EXAMPLE 1

As shown in FIG. 17, a barrier layer 202 of TaN with a thickness of about 20 nm was formed on a silicon substrate 200, and an oxide film in the surface of the barrier layer 202 was removed by wet processing. Thereafter, a Pd catalyst was imparted to the surface of the barrier layer 202, and a copper layer (copper seed layer) 204 with a thickness of about 50 nm was formed on the barrier layer 202 by electroless plating, thereby preparing a sample. The series of operations after the formation of the barrier layer 202 to the formation of the copper layer 204, including transport of the substrate, were carried out in a N₂ gas atmosphere. FIG. 17 is a diagram schematically showing a TEM (transmission electron microscope) image of the sample, including the interface between the barrier layer 202 and the copper layer 204. As can be seen from FIG. 17, there is no formation of an oxide film at the interface between the barrier layer 202 and the copper layer 204 (in the surface of the barrier layer 202).

### EXAMPLE 2

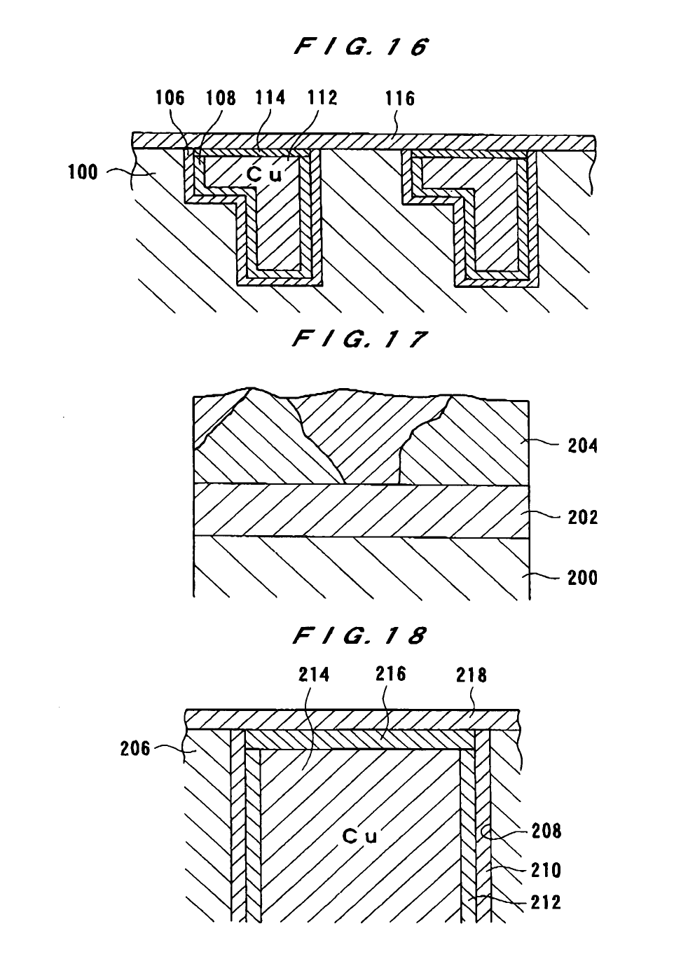

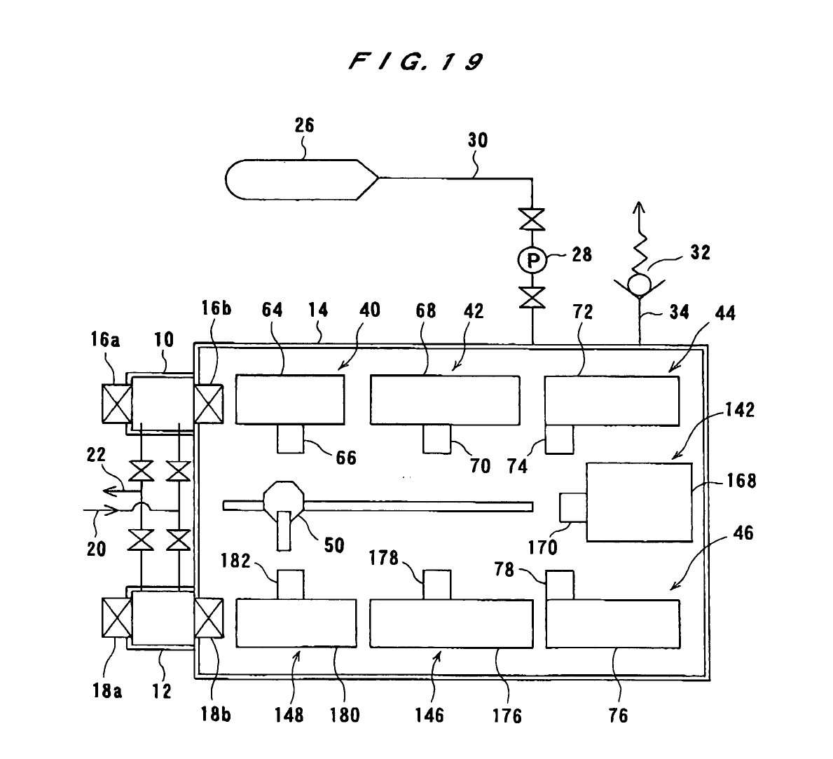

As shown in FIG. 18, interconnect trenches 208 were formed in an interlevel dielectric layer 206 of SiO₂ deposited on a surface of a silicon substrate, and a barrier layer 210 of TaN and a copper seed layer 212 were formed in this order on the entire surface. Thereafter, copper electroplating was carried out to embed copper into the interconnect trenches 208, followed by CMP to flatten the surface, thereby forming copper interconnects 214 in the interlevel dielectric layer 206. A protective film (cap material) 216 of a CoWP alloy with a thickness of about 20 nm was formed by electroless plating on the surfaces of the copper interconnects 214 to protect the interconnects 214, and an interlevel barrier layer 218 of SiN was formed on the entire surface, thereby preparing a sample. The series of operations from the formation of the copper seed layer 212 to the formation of the interlevel barrier layer 218, including transport of the substrate, were carried out in a N₂ gas atmosphere. FIG. 18 is a diagram schematically showing a TEM (transmission electron microscope) image of the sample, including the interface between the protective film 216 and the interlevel barrier layer 218. As can be seen from FIG. 18, there is no formation of an oxide film at the interface between the protective film 216 and the interlevel barrier layer 218 (in the surface of the protective film 216).

### COMPARATIVE EXAMPLE 1

Similarly to Example 1, a barrier layer 202 of TaN with a thickness of about 20 nm was formed on a silicon substrate 200, and an oxide film in the surface of the barrier layer 202 was removed by wet processing. Thereafter, a Pd catalyst was imparted to the surface of the barrier layer 202, and a copper layer (copper seed layer) 204 with a thickness of about 50 nm was formed on the barrier layer 202 by electroless plating, thereby preparing a sample. The series of operations were carried out in the air. FIG. 5 is a diagram schematically showing a TEM (transmission electron microscope) image of the sample, including the interface between the barrier layer 202 and the copper layer 204. As shown in FIG. 5, an oxide film 202a of the metal (Ta) constituting the barrier layer 202, having a thickness of about 5 nm, was formed at the interface between the barrier layer 202 and the copper layer 204 (in the surface of the barrier layer 202). In this regard, it is considered that even though the oxide film in the surface of the barrier layer 202 is removed by wet processing, the Ta oxide film 202a is again formed in the surface of the barrier layer 202 during electroless plating because it is carried out in the air.

### COMPARATIVE EXAMPLE 2

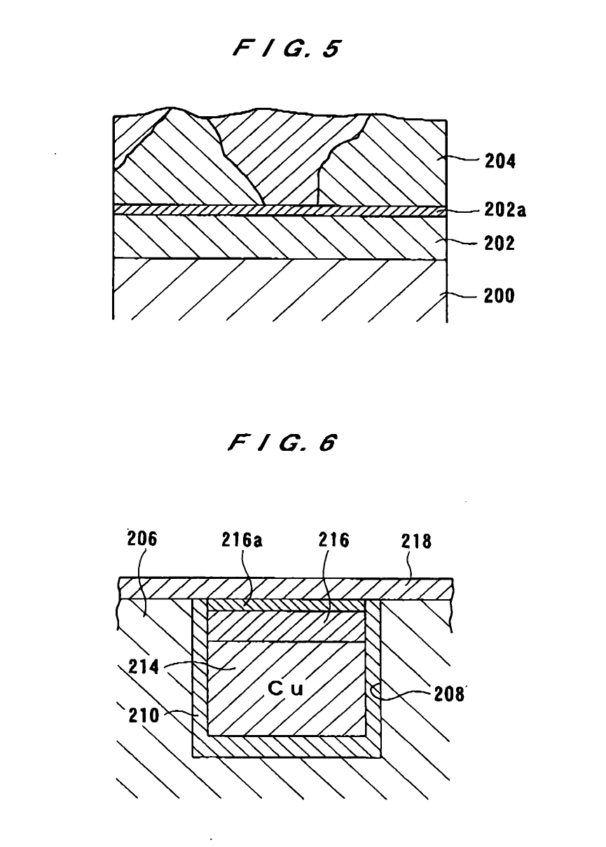

Similarly to Example 2, interconnect trenches 208 were formed in an interlevel dielectric layer 206 of SiO₂ deposited on a surface of a silicon substrate, and a barrier layer 210 of TaN was formed on the entire surface. Thereafter, copper was embedded into the interconnect trenches 208, followed by CMP to flatten the surface, thereby forming copper interconnects 214 in the interlevel dielectric layer 206. A protective film (cap material) 216 of a CoWP alloy with a thickness of about 20 nm was formed by electroless plating on the surfaces of the copper interconnects 214 to protect the interconnects 214, and an interlevel barrier layer 218 of SiN was formed on the entire surface, thereby preparing a sample. The series of operations were carried out in the air. FIG. 6 is a diagram schematically showing a TEM (transmission electron microscope) image of the sample, including the interface between the protective film 216 and the interlevel barrier layer 218. As shown in FIG. 6, a Co oxide film 216a having a thickness of about 3 nm was formed at the interface between the protective film 216 and the interlevel barrier layer 218 (in the surface of the protective film 216). In this regard, it is considered that Co is a metal that oxidizes easily.

As described hereinabove, according to the present invention, a series of process steps of forming a barrier layer on a surface of a substrate and forming a seed layer on a surface of the barrier layer, a series of process steps of flattening a surface of a substrate and forming a protective film selectively on the exposed surfaces of embedded interconnects which have been exposed by the flattening, or a series of process steps of forming a protective film selectively on the exposed surfaces of embedded interconnects and forming an interlevel barrier layer on the surface of the substrate having the thus-formed protective film, are carried out in a controlled atmosphere in the apparatus frame without being exposed to an oxidizing atmosphere as in the air. This makes it possible to form the seed layer on the surface of the barrier layer or form the interlevel barrier layer on the surface of the protective film while preventing the formation of an oxide film in the surface of the barrier layer or in the surface of the protective film.

FIG. 19 shows an overall layout plan of an interconnects-forming apparatus according to another embodiment of the present invention. With reference to the apparatus of this embodiment, the same or equivalent members as or to the members of the preceding embodiment shown in FIGS. 7 and 8 are given the same reference numerals, and a duplicate description thereof is omitted.

In the interior of the apparatus frame 14 are housed an embedding apparatus (film-forming apparatus) 40, a heat treatment apparatus 42, a flattening apparatus 44, a reduction apparatus 142, an electroless plating apparatus as a protective film-forming apparatus 46, a residue removal apparatus 146 and a cleaning/drying apparatus 148, which are disposed along a substrate transport route. A movable transport robot 50 as a transport device is disposed in a position surrounded by the apparatuses.

The reduction apparatus 142 is to reduce a copper oxide film formed in the outermost surfaces of interconnects (copper interconnects) which have been exposed on the surface of a substrate by flattening in the above-described flattening apparatus 44, thereby returning the oxide film to the original non-oxidized metal state having no oxide film in the outermost surfaces of interconnects. Thus, the reduction apparatus 142 can avoid the need to etch away an oxide film and can therefore keep the flattened surfaces of interconnects after polishing such as CMP. According to this embodiment, the reduction apparatus 142 includes a processing chamber 168 capable of replacing the internal atmosphere with an inert gas (e.g. N₂ gas) atmosphere, and an atmosphere adjustment mechanism 170 having the same construction as the above-described atmosphere adjustment mechanism 58 of the barrier layer-forming apparatus (sputtering apparatus) 36.

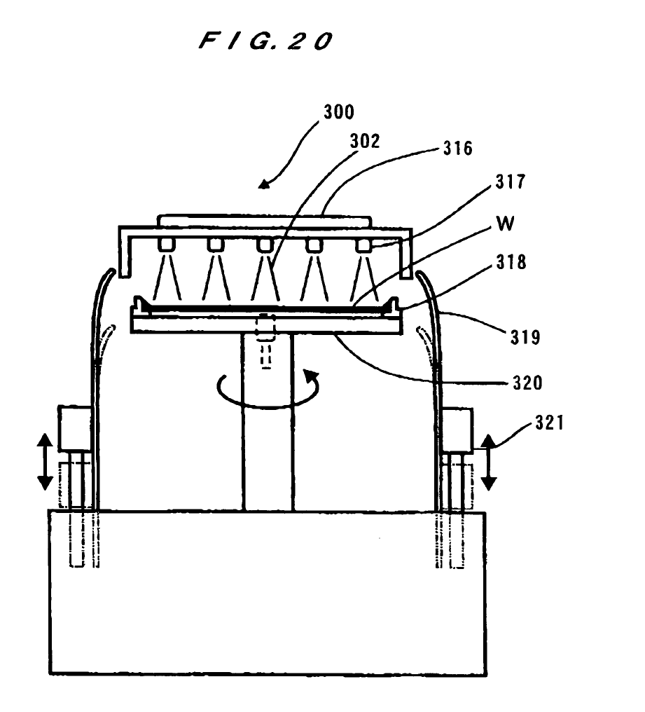

According to this embodiment, a processing section 300, as shown in FIG. 20, is provided in the processing chamber 168. The processing section 300 includes a substrate chuck 318, a turntable 320 for horizontally holding and rotating a substrate W with its front surface (plating surface) facing upwardly, and a spray nozzle 316 disposed above the turntable 320 and having a member of downwardly-oriented spray heads 317. The turntable 320 and the spray heads 317 are surrounded by a sidewall 319 that is vertically movable by sliders 321.

According to the processing section 300, an aqueous reducing solution 302, for example a solution containing an alkylamine borane or a borohydride compound, or a cathode water (hydrogen-containing water), is sprayed from the spray heads 317 toward the surface (plating surface) of the substrate W held and rotating on the turntable 320 so as to bring the aqueous reducing solution 302 into contact with the surface (plating surface) of the substrate W, whereby a copper oxide film, formed in the outermost surfaces of interconnects, can be reduced. Though not shown diagrammatically, the processing section 300 is designed to remove a processing liquid (aqueous reducing solution) adhering to the surface of a substrate by scattering the liquid with an inert gas. Thus, the processing liquid, which has been used for the reduction of an oxide film in the outermost surfaces of interconnects and is adhering to the substrate surface, is removed without carrying out water-cleaning using e.g. pure water containing dissolved oxygen. This can avoid re-formation of an oxide film in the outermost surfaces of interconnects upon removal of the processing liquid.

It is also possible to provide a processing tank for storing an aqueous reducing solution and immerse a substrate in the aqueous reducing solution in the processing tank. Further, it is possible to house a substrate in the processing chamber 168 and put the interior of the processing chamber 168 in an atmosphere containing active hydrogen (hydrogen radical), for example, a H₂ plasma atmosphere or HN₃ plasma atmosphere, thereby reducing an oxide film in the outermost surfaces of interconnects.

The residue removal apparatus 146 is to remove a copper residue, which has not been removed upon flattening and remains on an insulating film, and on which the protective film material has been grown by the electroless plating, after the formation of a protective film by electroless plating. According to this embodiment, the residue removal apparatus 146 is comprised of a scrub cleaning apparatus which includes a processing chamber 176 capable of replacing the internal atmosphere with an inert gas (e.g. N₂ gas) atmosphere and an atmosphere adjustment mechanism 178 having the same construction as the above-described atmosphere adjustment mechanism 58 of the barrier layer-forming apparatus (sputtering apparatus) 36. By thus forming a protective film by electroless plating without removing a copper residue remaining on an insulating film, and removing the copper residue, after growing the protective film material on the residue and thereby making the residue larger, by the residue removal apparatus (scrub cleaning apparatus) 146, the residue on the insulating film can be removed securely, whereby the selectivity of the protective film formation can be enhanced.

The cleaning/drying apparatus 148 is to clean (rinse) and dry the substrate after the removal of residues in the residue removal apparatus 146 and, according to this embodiment, includes a processing chamber 180 capable of replacing the internal atmosphere with an inert gas (e.g. N₂ gas) atmosphere, and an atmosphere adjustment mechanism 182 having the same construction as the above-described atmosphere adjustment mechanism 58 of the barrier layer-forming apparatus (sputtering apparatus) 36. In the cleaning/drying apparatus 148, chemical cleaning and pure water cleaning (rinsing) of the surface of the substrate are carried out, followed by spindle rotation of the substrate for complete drying.

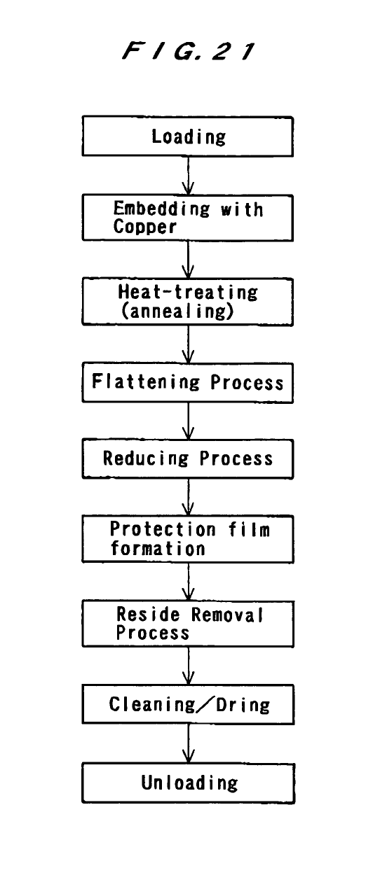

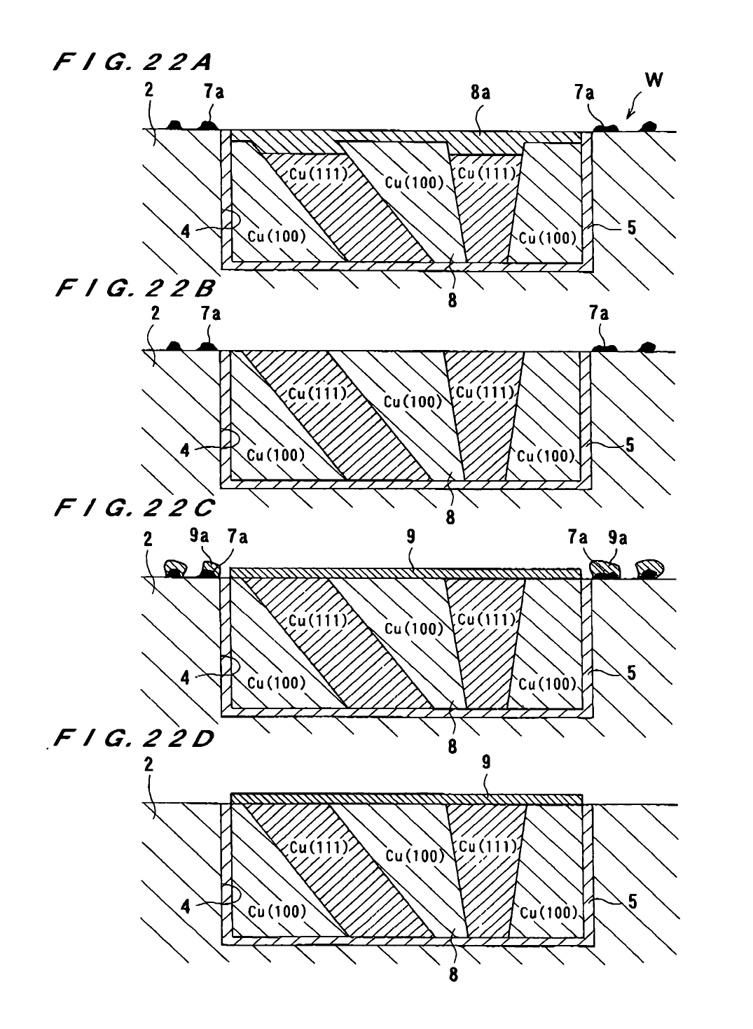

A sequence of processes for forming interconnects by the interconnects-forming apparatus will now be described by referring to FIGS. 21 and 22.

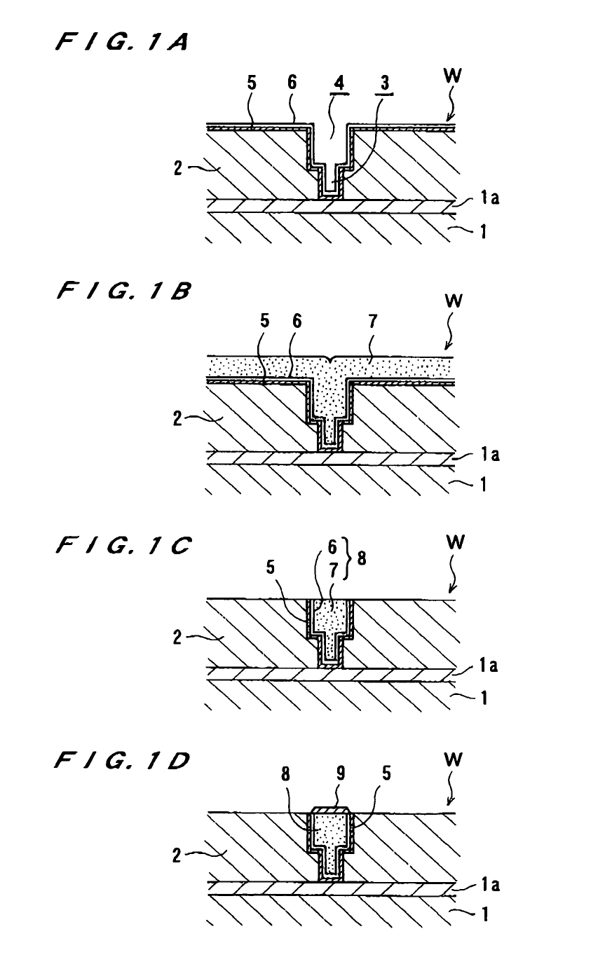

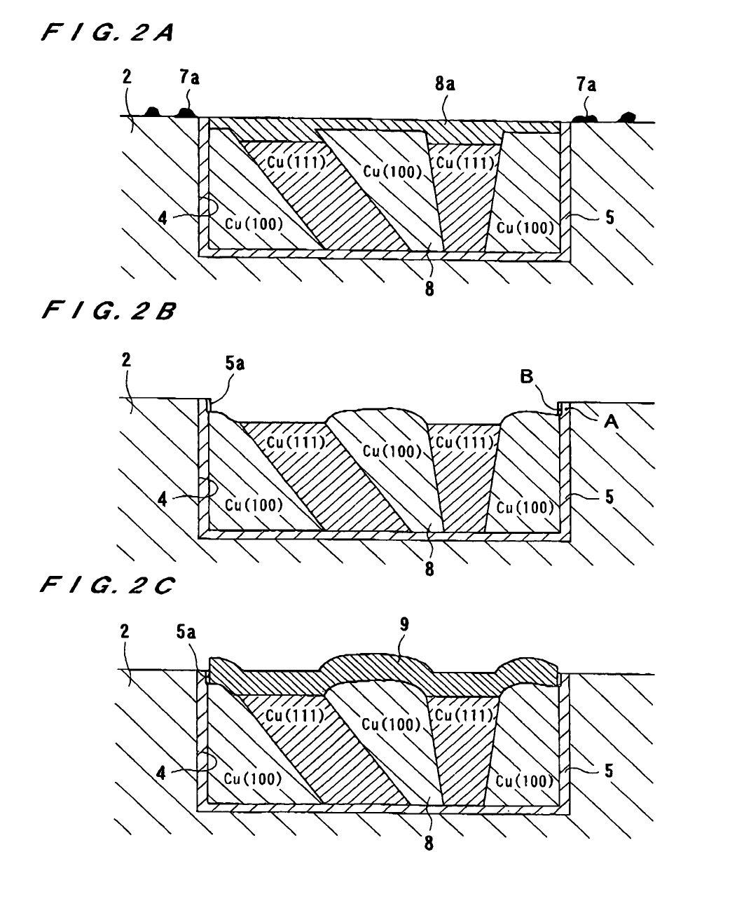

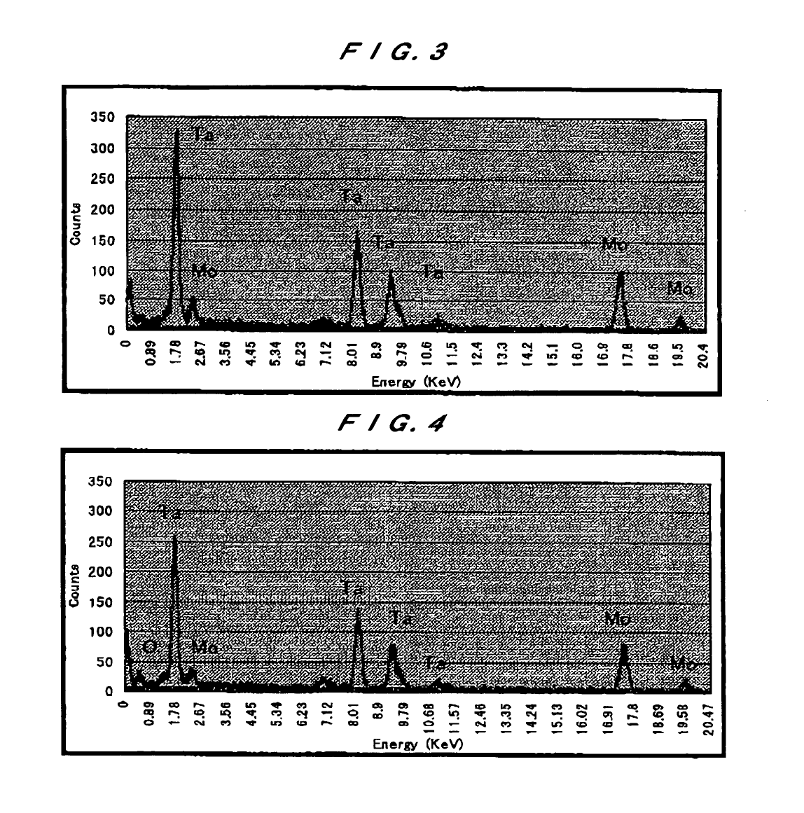

First, as shown in FIG. 1A, a substrate W is prepared by forming as interconnect recesses contact holes 3 and interconnect trenches 4 in an insulating film 2, and then forming a barrier layer 5 of TaN or the like and a seed layer 6 as an electric feeding layer for electroplating in this order on the entire surface. Such substrates W are housed in a cassette, and the cassette is carried in the loading chamber 10. At the same time, an empty cassette is carried in the unloading chamber 12. Thereafter, the internal atmosphere of each of the loading chamber 10 and the unloading chamber 12 is replaced with an inert gas atmosphere such as N₂ gas.

Similarly, while evacuating the apparatus frame 14 through the gas discharge line 34, an inert gas, such as N₂ gas, is supplied through the inert gas supply line 30 into the apparatus frame 14, thereby replacing the internal atmosphere with the inert gas atmosphere at a higher pressure than atmospheric pressure. Thereafter, the gate valves 16b, 18b at the outlets on the apparatus frame 14 sides of the loading chamber 10 and the unloading chamber 12 are opened.

Next, the substrates W are taken one by one by the transport robot 50 out of the cassette in the loading chamber 10, and the substrate W is carried in the processing chamber 64, whose interior is kept in an inert gas (e.g. N₂ gas) atmosphere by the atmosphere adjustment mechanism 66, of the embedding apparatus (electroplating apparatus) 40. As necessary, the initial film thickness (thickness of the seed layer 6) is measured with a film thickness measuring device (not shown).

In the embedding apparatus 40, as shown in FIG. 1B, a copper layer 7 is deposited on the surface of the substrate W, thereby effecting embedding of copper into the contact holes 3 and the interconnect trenches 4. The substrate W after plating is rotated at a high speed to spin-dry the substrate W.

The substrate W having the thus-formed copper layer 7 is carried in the processing chamber 68 of the heat treatment apparatus (lamp annealing apparatus) 42. In the heat treatment apparatus 42, the substrate W is subjected to heat treatment (lamp annealing), for example, at 350° C. for 5 minutes in a N₂ gas atmosphere.

The substrate W after the annealing is carried in the processing chamber 72, whose interior is kept in an inert gas (e.g. N₂ gas) atmosphere, of the flattening apparatus (CMP apparatus) 44. In the flattening apparatus 44, as shown in FIG. 1C, the unnecessary copper layer 7, seed layer 6 and barrier layer 5 deposited on the insulating film 2 are polished and removed, and the surface of the substrate W is flattened, thereby forming interconnects 8 of copper (copper interconnects) in the insulating film 2. The surface of the substrate W after the flattening is cleaned with a chemical and further cleaned (rinsed) with pure water, and the substrate W is then rotated at a high speed to spin-dry the substrate W.

When the barrier layer 5, the seed layer 6 and the copper layer 7 on the insulating film 2 are thus removed into a flat surface to form interconnects 8 of copper, a copper residue 7a remains on the surface of the insulating film 2 and a thin copper oxide film 8a is formed in the outermost surfaces of interconnects 8, as shown in FIG. 22A. The depth of the copper oxide film 8a is not uniform over the entire surfaces of interconnects 8 due to a difference in the oxidization speed which is caused by a difference in the crystal orientation of copper constituting the interconnects 8, for example, a difference in the oxidization speed between copper with crystal orientation (111) and copper with crystal orientation (100). Thus, there is variation (non-uniformity) in the thickness of the copper oxide film 8a formed in the outermost surfaces of the interconnects 8.

The substrate W after the flattening process is carried in the processing chamber 168, whose interior is kept in an inert gas (e.g. N₂ gas) atmosphere, of the reduction apparatus 142. In the reduction apparatus 142, the copper oxide film 8a, formed in the outermost surfaces of the interconnects 8 exposed on the surface of the substrate W, is reduced into the original non-oxidized metal state, thereby forming interconnects 8 which have no oxide film in the outermost surface and thus do not require etching removal of an oxide film and which have been flattened by polishing such as CMP, as shown in FIG. 22B.

The no need to etch away an oxide film can avoid the decrease in volume of the interconnects 8, thus avoiding a rise in the interconnect resistance. Further, there is no exposure of the barrier layer 5 associated with etching of the copper oxide film. Accordingly, there is no fear of the formation of an oxide film in the surface of the barrier layer 5. Furthermore, since the flattened surfaces of interconnects 8 can be kept as they are, a protective film 9 having a flat surface can be formed by electroless plating selectively on the flat surfaces of interconnects 8, as described below.

The substrate W after the reduction progressing is carried in the processing chamber 76, whose interior is kept in an inert gas (e.g. N₂ gas) atmosphere, of the electroless plating apparatus as the protective film-forming apparatus 46. In the protective film-forming apparatus (electroless plating apparatus) 46, the substrate W is immersed in an electroless CoWB-plating solution, held in a plating tank, for example at 80° C. for three minutes. Thereafter, the surface of the substrate W after plating is allowed to be in contact with a post-cleaning liquid in a post-cleaning tank to carry out post-cleaning of the substrate W, and the substrate W is then rotated at a high speed to spin-dry the substrate W. A protective film 9 of a CoWB alloy with a thickness of e.g. 20 nm is thus formed on the surfaces of interconnects 8, formed in the insulating film 2, to protect the interconnects 8, as shown in FIG. 22C.

By thus forming the protective film 9by electroless plating on the flat surfaces of interconnects 8, it is possible to provide the protective film 9 with a flat surface. This can prevent poor contact with upper-level interconnects and undulation of the surface of an interlevel dielectric layer which is formed in the next process step. When forming the protective film 9 by electroless plating without removing the copper residue 7a remaining on the surface of insulating film 2, the protective film material 9a grows on the copper residue 7a with the copper residue 7a as a nucleus, as shown in FIG. 22c.

Next, the substrate W having the thus-formed protective film 9 is carried in the processing chamber 176, whose interior is kept e.g. in a N₂ gas atmosphere, of the residue removal apparatus 146. In the residue removal apparatus 146, the substrate W is subjected to scrub cleaning, for example, using a roll sponge and an alkaline solution containing a surfactant, thereby removing the copper residue 7a which has not been removed upon the flattening and remains on the surface of the insulating film 2 and on which the protective film material 9a has been grown by the electroless plating, as shown in FIG. 22D. The copper residue 7a on which the protective film material 9a has been grown is a mere deposit having no chemical bond to the insulating film 2, and therefore it can be peeled from the surface of the insulating film 2 easily and securely, for example, by scrub cleaning with a roll sponge. It has been confirmed that such a very small amount of copper residue that is not detachable with AES but only detectable with TOF-SIMS can be removed by scrub cleaning.

The substrate W after the residue removal processing is carried in the processing chamber 180, whose interior is kept e.g. in a N₂ gas atmosphere, of the cleaning/drying apparatus 148. After cleaning (rinsing) and spin-drying the substrate W in the cleaning/drying apparatus 148, the substrate is carried by the transport robot 50 into the cassette in the unloading chamber 12.

Though in this embodiment copper is used as an interconnect material, it is also possible to use a copper alloy, silver, a silver alloy, tungsten or a tungsten alloy other than copper. Further, though a CoWB alloy is used for the protective film 9, it is also possible to use a Co alloy other than CoWB, such as a CoWP alloy, a CoP alloy or a CoB alloy. Furthermore, Ni or a Ni alloy may also be employed.

### EXAMPLE 3

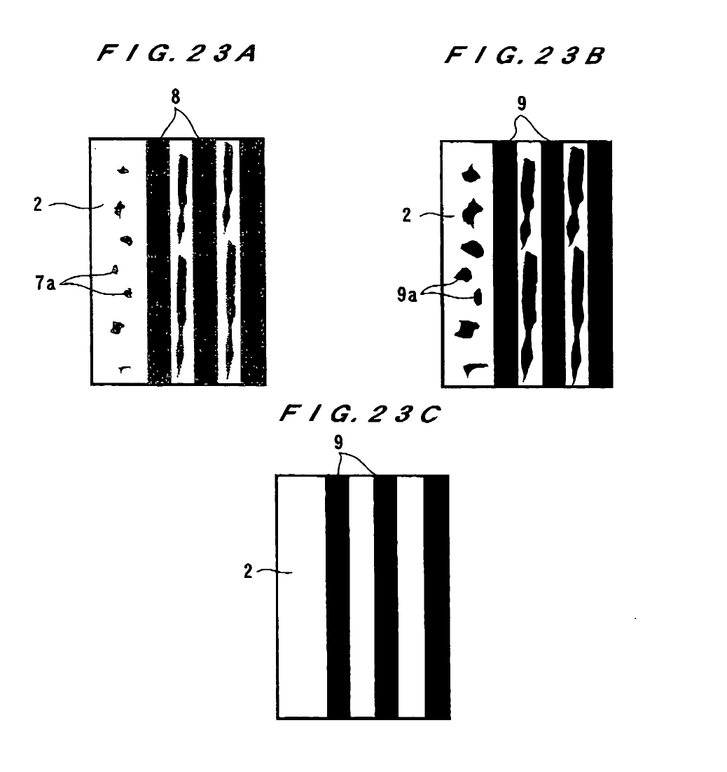

Interconnect trenches having a width of 0.25 μm were formed at intervals of 0.25 μm in an insulating film on a silicon substrate, and copper was embedded by copper plating into the interconnect trenches, followed by CMP to remove extra copper, thereby forming copper interconnects. FIG. 23A schematically shows a TOF-SIMS ion image of the sample. As apparent from FIG. 23A, a number of copper residues 7a remain on the portion between interconnects 8 of the surface of the insulating film 2.

Next, the surface of the substrate was allowed to be in contact with an aqueous reducing solution containing 6 g/L of DMAB (dimethylamine borane) at 70° C. for one minute. Thereafter, the substrate was immersed in an electroless plating solution having the following composition at 80° C. for one minute, thereby forming a protective film selectively on the surfaces of the interconnects.

Plating Solution Composition

| | |
|---|---|
| CoSO₄.7H₂O | 0.10 mol/L |
| L-tartaric acid | 0.50 mol/L |
| (NH₄)₂SO₄ | 0.20 mol/L |
| H₂WO₄ | 0.10 mol/L |
| DMAB | 0.02 mol/L |
| TMAH (27%) | 0.80 mol/L |
| pH = 9 | |

FIG. 23B schematically shows a TOF-SIMS ion image of the sample after plating. FIG. 23B indicates the selective formation of protective film 9 on the interconnects and also indicates the growth of the protective film material 9a on the copper residues remaining on the insulating film 2.

The surface of the substrate was then subjected to cleaning with a sponge roll using an alkaline solution containing a surfactant, thereby removing the copper residues on which the interconnect material had grown. FIG. 23C schematically shows a TOF-SIMS ion image of the sample after cleaning. FIG. 23C indicates complete removal of the copper residues from the surface of the insulating film 2.

As described hereinabove, the present invention can avoid the need to etch away an oxide film. This can avoid a decrease in volume of interconnects and prevent the formation of an oxide film in the surface of a barrier layer upon forming protective film. Further, the flattened surfaces of interconnects after polishing, such as CMP, can be kept as they are. Accordingly, a protective film having a flat surface can be formed with high selectivity on the surfaces of interconnects.

Although certain preferred embodiments of the present invention have been shown and described in detail, it should be understood that various changes and modifications may be made therein without departing from the scope of the appended claims.

1. An interconnects-forming apparatus for forming embedded interconnects in a surface of a substrate, comprising:
a barrier layer-forming apparatus for forming a barrier layer on a surface of a substrate;
a metal layer-forming apparatus for forming a metal layer on a surface of the barrier layer formed in the barrier layer-forming apparatus; and
an apparatus frame capable of controlling the internal atmosphere;
wherein the barrier layer-forming apparatus and the metal layer-forming apparatus are disposed in the apparatus frame.

2. The interconnects-forming apparatus according to claim 1, wherein the metal layer is a seed layer or an interconnect layer.

3. The interconnects-forming apparatus according to claim 1, wherein the barrier layer-forming apparatus and/or the metal layer-forming apparatus includes a processing chamber capable of controlling the internal atmosphere.

4. The interconnects-forming apparatus according to claim 1, wherein the substrate, which is carried in the apparatus frame, has an interlevel dielectric layer which has been formed by PVD, CVD or a wet coating method, and an interconnect pattern which has been formed in the interlevel dielectric layer by RIE, CDE, sputter etching or wet etching.

5. The interconnects-forming apparatus according to claim 1, wherein the barrier layer-forming apparatus is comprised of a PVD apparatus, a CVD apparatus or a wet plating apparatus.

6. The interconnects-forming apparatus according to claim 1, wherein the metal layer-forming apparatus is comprised of a wet plating apparatus.

7. The interconnects-forming apparatus according to claim 6, wherein the wet plating apparatus uses a liquid having a dissolved oxygen concentration of not more than 5 ppb as a processing liquid.

8. The interconnects-forming apparatus according to claim 6, wherein the wet plating apparatus is designed to remove a solution adhering to the substrate by scattering the solution with an inert gas.

9. The interconnects-forming apparatus according to claim 1, wherein a transport device for transporting the substrate between the apparatuses is disposed in the apparatus frame.

10. The interconnects-forming apparatus according to claim 1, wherein the interior of the apparatus frame is kept in a vacuum atmosphere or an inert gas atmosphere.

11. The interconnects-forming apparatus according to claim 1, wherein the metal layer in a seed layer, and the interconnects-forming apparatus further comprises in the apparatus frame an embedding apparatus for embedding an interconnect material into interconnect recesses provided in the surface of the substrate.

12. The interconnects-forming apparatus according to claim 11, wherein the embedding apparatus is comprised of a PVD apparatus, a CVD apparatus or a wet plating apparatus.

13. The interconnects-forming apparatus according to claim 11, further comprising:
a heat treatment apparatus, disposed in the flame apparatus, for heat-treating the interconnect material embedded in the interconnect recesses.

14. The interconnects-forming apparatus according to claim 13, wherein the heat treatment apparatus includes a radiation heat oven, a reflected heat oven, a hot plate oven, a heat convection oven, or a lamp annealing oven.

15. An interconnects-forming apparatus for forming embedded interconnects in a surface of a substrate, comprising:
a flattening apparatus for removing an extra metal film formed on a surface of a substrate and flattening the surface of the substrate;
a protective film-forming apparatus for forming a protective film selectively on the exposed surfaces of embedded interconnects which has been exposed by the flattening; and
an apparatus frame capable of controlling the internal atmosphere;
wherein the flattening apparatus and the protective film-forming apparatus are disposed in the apparatus frame.

16. The interconnects-forming apparatus according to claim 15, wherein the flattening apparatus and/or the protective film-forming apparatus include a processing chamber capable of controlling the internal atmosphere.

17. The interconnects-forming apparatus according to claim 15, wherein the flattening apparatus is comprised of a CMP apparatus or a wet polishing apparatus.

18. The interconnects-forming apparatus according to claim 15, wherein a transport device for transporting the substrate between the apparatuses is disposed in the apparatus frame.

19. The interconnects-forming apparatus according to claim 15, wherein the interior of the apparatus frame is kept in a vacuum atmosphere or an inert gas atmosphere.

20. The interconnects-forming apparatus according to claim 15, further comprising:
an embedding apparatus, disposed in the apparatus frame, for embedding an interconnect material into interconnect recesses provided in the surface of the substrate.

21. The interconnects-forming apparatus according to claim 20, wherein the embedding apparatus is comprised of a PVD apparatus, a CVD apparatus or a wet plating apparatus.

22. The interconnects-forming apparatus according to claim 20, further comprising;
a heat treatment apparatus, disposed in the flame apparatus, for heat-treating the interconnect material embedded in the interconnect recesses.

23. The interconnects-forming apparatus according to claim 22, wherein the heat treatment apparatus includes a radiation heat oven, a reflected heat oven, a hot plate oven, a heat convection oven, or a lamp annealing oven.

24. An interconnects-forming apparatus for forming embedded interconnects in a surface of a substrate, comprising:
a protective film-forming apparatus for forming a protective film selectively on the exposed surfaces of embedded interconnects;
an interlevel barrier layer-forming apparatus for forming an interlevel barrier layer on a surface of a substrate having the thus-formed protective film; and
an apparatus frame capable of controlling the internal atmosphere;
wherein the protective film-forming apparatus and the interlevel barrier layer-forming apparatus are disposed in the apparatus frame.

25. The interconnects-forming apparatus according to claim 24, wherein the protective film-forming apparatus and/or the interlevel barrier layer-forming apparatus include a processing chamber capable of controlling the internal atmosphere.

26. The interconnects-forming apparatus according to claim 24, wherein the protective film-forming apparatus is comprised of a wet plating apparatus.

27. The interconnects-forming apparatus according to claim 26, wherein the wet plating apparatus uses a liquid having a dissolved oxygen concentration of not more than 5 ppb as a processing liquid.

28. The interconnects-forming apparatus according to claim 26, wherein the wet plating apparatus is designed to remove a solution adhering to the substrate by scattering the solution with an inert gas.

29. The interconnects-forming apparatus according to claim 24, wherein a transport device for transporting the substrate between the apparatuses is disposed in the apparatus frame.

30. The interconnects-forming apparatus according to claim 24, wherein the interior of the apparatus frame is kept in a vacuum atmosphere or an inert gas atmosphere.

31. The interconnects-forming apparatus according to claim 24, further comprising:
an embedding apparatus, disposed in the apparatus frame, for embedding an interconnect material into interconnect recesses provided in the surface of the substrate.

32. The interconnects-forming apparatus according to claim 31, wherein the embedding apparatus is comprised of a PVD apparatus, a CVD apparatus or a wet plating apparatus.

33. The interconnects-forming apparatus according to claim 31, further comprising:
a heat treatment apparatus, disposed in the flame apparatus, for heat-treating the interconnect material embedded in the interconnect recesses.

34. The interconnects-forming apparatus according to claim 33, wherein the heat treatment apparatus includes a radiation heat oven, a reflected heat oven, a hot plate oven, a heat convection oven, or a lamp annealing oven.

35. A method for forming interconnects, comprising;
embedding an interconnect material into interconnect recesses formed in an insulating film formed on a substrate;
removing an extra interconnect material on the insulating film and flattening the surface, thereby forming interconnects in the interconnect recesses;
reducing an oxide film in the outermost surfaces of the interconnects; and
forming a protective film selectively on the reduced surfaces of the interconnects by electroless plating.

36. The method according to claim 35, wherein the oxide film in the outermost surfaces of the interconnects is reduced by wet processing with a reducing solution.

37. The method according to claim 36, wherein the reducing solution is a solution containing an alkylamine borane or a borohydride compound, or a cathode water.

38. The method according to claim 35, wherein the oxide film in the outermost surfaces of the interconnects is reduced by dry processing in an active hydrogen-containing atmosphere.

39. The method according to claim 38, wherein the active hydrogen-containing atmosphere is a H₂ plasma atmosphere or a NH₃ plasma atmosphere.

40. The method according to claim 35, wherein the interconnect material embedded in the interconnect recesses is subjected to heat treatment.

41. The method according to claim 35, wherein after the formation of the protective film by electroless plating, a residue, which has not been removed by the flattening step and remains on the surface of the insulating film and on which the protective film material has been grown by the electroless plating, is removed.

42. The method according to claim 41, wherein the residue on which the protective film material has been grown is removed by mechanically peeling the residue from the surface of the insulating film.

43. The method according to claim 35, wherein the interconnect material is Cu, a Cu alloy, Au, an Au alloy, W, or a W alloy.

44. The method according to claim 35, wherein the protective film is Co, a Co alloy, Ni, or a Ni alloy.

45. An interconnects-forming apparatus comprising:
a flattening apparatus for removing an extra interconnect material on an insulating film which is formed on a substrate and in which interconnect recesses are formed, and flattening the surface, thereby forming interconnects in the interconnect recesses;
a reduction apparatus for reducing an oxide film in the outermost surfaces of the interconnects; and
an electroless plating apparatus for forming a protective film selectively on the reduced surfaces of the interconnects.

46. The interconnects-forming apparatus according to claim 45, wherein the reduction apparatus and the electroless plating apparatus are disposed in an apparatus frame capable of controlling the internal atmosphere.

47. The interconnects-forming apparatus according to claim 45, wherein the reduction apparatus is designed to remove a solution adhering to the substrate by scattering the solution with an inert gas.

48. The interconnects-forming apparatus according to claim 45, further comprising:
a residue removal apparatus for removing a residue which has not been removed by the flattening and remains on the surface of the insulating film and on which the protective film material has been grown by electroless plating.

49. The interconnects-forming apparatus according to claim 48, wherein the residue removal apparatus is comprised of a scrub cleaning apparatus.

50. The interconnects-forming apparatus according to claim 45, further comprising:
a heat treatment apparatus for heat-treating the interconnect material embedded in the interconnect recesses.

51. An interconnects-forming apparatus comprising:
an embedding apparatus for embedding an interconnect material into interconnect recesses formed in an insulating film formed on a substrate;
a flattening apparatus for removing an extra interconnect material on the insulating film and flattening the surface, thereby forming interconnects in the interconnect recesses;
a reduction apparatus for reducing an oxide film in the outermost surfaces of the interconnects; and
an electroless plating apparatus for forming a protective film selectively on the reduced surfaces of the interconnects by electroless plating.

52. The interconnects-forming apparatus according to claim 51, wherein the reduction apparatus and the electroless plating apparatus are disposed in an apparatus frame capable of controlling the internal atmosphere.

53. The interconnects-forming apparatus according to claim 51, wherein the reduction apparatus is designed to remove a solution adhering to the substrate by scattering the solution with an inert gas.

54. The interconnects-forming apparatus according to claim 51, further comprising:
a residue removal apparatus for removing a residue which has not been removed by the flattening and remains on the surface of the insulating film and on which the protective film material has been grown by electroless plating.

55. The interconnects-forming apparatus according to claim 54, wherein the residue removal apparatus is comprised of a scrub cleaning apparatus.

56. The interconnects-forming apparatus according to claim 51, further comprising:
a heat treatment apparatus for heat-treating the interconnect material embedded in the interconnect recesses.
